(19) United States
(12) Patent Application Publication
(10) Pub. No.: US 2021/0238749 A1
(43) Pub. Date: Aug. 5, 2021

(54) METHOD FOR FABRICATING GOLD FINE PARTICLES

(71) Applicant: Nippon Telegraph and Telephone Corporation, Tokyo (JP)

(72) Inventors: Kota Tateno, Tokyo (JP); Satoshi Sasaki, Tokyo (JP); Guoqiang Zhang, Tokyo (JP); Masato Takiguchi, Tokyo (JP)

(73) Assignees: Nippon Telegraph and Telephone Corporation, Tokyo (JP); Nippon Telegraph and Telephone Corporation, Tokyo (JP)

(21) Appl. No.: 17/258,602

(22) PCT Filed: Jul. 29, 2019
(86) PCT No.: PCT/JP2019/029579

§ 371 Date: Jan. 7, 2021

(30) Foreign Application Priority Data
Jul. 31, 2018 (JP) 2018-143248

(51) Int. Cl. C23C 18/42; H01L 21/02

(52) U.S. Cl. CPC C23C 18/42; B82Y 40/00; H01L 21/02601; H01L 21/02521

(57) ABSTRACT

First, in a first step S101, a semiconductor layer composed of a p type Group III-V compound semiconductor is prepared. The semiconductor layer may be composed of a Group III-V compound semiconductor crystal. Next, in a second step S102, gold is grown on a surface of the above semiconductor layer according to an electroless plating method to form fine gold particles. In this step, for example, an electroless plating solution of gold is brought into contact with a surface of the semiconductor layer such as by immersing the semiconductor layer in the electroless gold plating solution. In addition, in this plating treatment, the liquid temperature of the electroless gold plating solution may be room temperature (about 20° C. to 30° C.).

### CROSS-REFERENCE TO RELATED APPLICATIONS

This application is a national phase entry of PCT Application No. PCT/JP2019/029579, filed on Jul. 29, 2019, which claims priority to Japanese Application No. 2018-143248, filed on Jul. 31, 2018, which applications are hereby incorporated herein by reference.

### TECHNICAL FIELD

Embodiments of the present invention relate to a production method of fine gold particles for producing fine gold particles used for forming nanowires according to a vapor-liquid-solid (VLS) growth method.

### BACKGROUND

Application of nanowires composed of Group III-V semiconductors having a diameter on a nanometer scale to optical devices such as solar cells and light emitting elements is being studied. These nanowires are produced in a bottom-up manner by crystal growth according to a metal-organic chemical vapor deposition method using fine gold particles as a catalyst. In this nanowire production application, it is important to arrange fine gold particles having a large particle diameter of 100 nm or more with a high density of 10⁷ cm⁻² or more.

When a solar cell is composed of nanowires, in order to efficiently absorb light, for example, for InP nanowires, a length of 2,000 nm, an optimal diameter of 180 nm, and an optimal interval of 360 nm are calculated (refer to Non Patent Literature 1). In this manner, when a nanowire is provided for a solar cell, a technology for a nanowire having a large diameter to grow with a high density is important. In addition, also in a nanowire light emitting element, as the diameter increases, the volume of an optical gain medium increases and the luminous intensity increases.

Regarding a method of producing fine gold particles used in formation of the above nanowire, for example, there is a technology in which a gold thin film is formed on a substrate by vapor deposition, and heated to form fine gold particles in a self-aligned manner. In addition, there is a method using a colloid solution containing fine gold particles.

In a method of forming a gold thin film and then performing heating, in a heat treatment at a high temperature, according to Ostwald ripening, large fine particles are generated, but large particles are formed at positions distant from each other. Therefore, in this method, it is difficult to arrange large fine particles with a high density [refer to FIG. 5].

In addition, in a method using a colloid solution containing fine gold particles, as shown in FIG. 6, the concentration of the colloid solution decreases as the particle diameter increases. Therefore, in this method, it is difficult to disperse large fine particles having a diameter of 100 nm or more on a substrate with a high density.

### CITATION LIST

### Non Patent Literature

NPL 1 J. Kupec et al., “Light absorption and emission in nanowire array solar cells”, Optics Express, vol. 18, no. 26, pp. 27589-27605, 2010.

### SUMMARY

### Technical Problem

As described above, in application of a nanowire to an optical device such as a solar cell and a light emitting element, it is important to form a thicker nanowire, and therefore it is necessary to form larger fine gold particles with a high density. However, in the above technology for producing fine gold particles, it is difficult to form fine gold particles having a large particle diameter with a high density. On the other hand, when a gold thin film is patterned using electron beam lithography, it is possible to form fine gold particles having a large particle diameter with a high density. However, in production of fine gold particles by patterning using lithography technology, there is a problem that a longer time is required for production. In addition, in order to produce more elements in a shorter time, it is important to form more elements on a large-area substrate, and as is well known, in the electron beam lithography technology, it is not easy to increase the area.

Embodiments of the present invention have been made in order to address the above problems, and an object of embodiments of the present invention is to form larger fine gold particles with a high density more easily.

### Means for Solving the Problem

A method of producing fine gold particles according to embodiments of the present invention includes a first step in which a semiconductor layer composed of a p type Group III-V compound semiconductor is prepared and a second step in which gold is grown on a surface of the semiconductor layer according to an electroless plating method to form fine gold particles. In this second step, an electroless plating solution of gold is brought into contact with the surface of the semiconductor layer.

In the method of producing fine gold particles, the semiconductor layer may be composed of a Group III-V compound semiconductor crystal. Here, the semiconductor layer may be a substrate composed of a Group III-V compound semiconductor, and the semiconductor layer may be formed on the substrate.

### Effects of Embodiments of the Invention

As described above, according to embodiments of the present invention, it is possible to obtain excellent effects that gold is plated and grown on the surface of a p type compound semiconductor layer according to a gold electroless plating method, and thus it is possible to form larger fine gold particles with a high density more easily.

### BRIEF DESCRIPTION OF THE DRAWINGS

FIG. 1 is a flowchart explaining a method of producing fine gold particles according to an embodiment of the present invention.

FIG. 2A is a picture showing results obtained by observing a surface of a p type InP (111) B substrate in Example 1 under a scanning electron microscope.

FIG. 2B is a picture showing results obtained by observing a surface of a p type GaAs (111) B substrate in Example 1 under a scanning electron microscope.

FIG. 3A is a picture showing results obtained by observing a nanowire actually produced using fine gold particles formed in Example 1 under a scanning electron microscope.

FIG. 3B is a picture showing results obtained by observing a nanowire actually produced using fine gold particles formed in Example 1 under a scanning electron microscope.

FIG. 4 is a characteristic diagram showing a plating treatment time when fine gold particles are plated and grown on a surface of a p-InP (i) B substrate using an electroless gold plating solution of Example 1 at a liquid temperature of 24° C., an average diameter of formed fine gold particles, and changes in the maximum value and the minimum value of the diameter.

FIG. 5 is a picture showing results obtained by observing the state of fine gold particles formed by a method of forming a gold thin film on a substrate and then performing heating, under a scanning electron microscope.

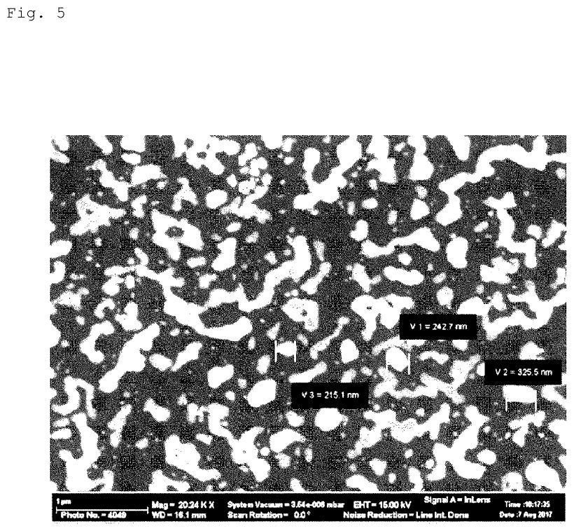

FIG. 6 is a characteristic diagram showing the relationship between the particle diameter of fine gold particles formed by a method using a colloid solution containing fine gold particles and the number of particles.

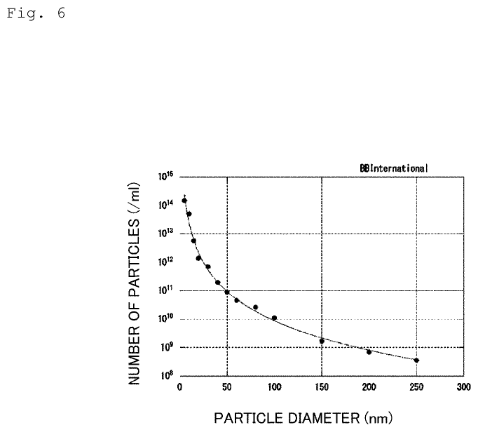

### DETAILED DESCRIPTION OF ILLUSTRATIVE EMBODIMENTS

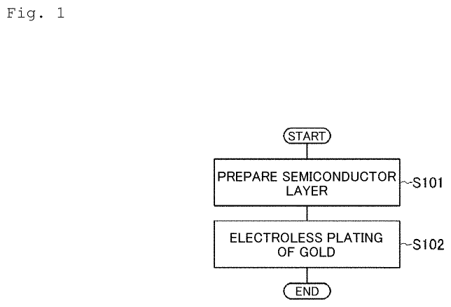

Hereinafter, a method of producing fine gold particles according to an embodiment of the present invention will be described with reference to FIG. 1.

First, in a first step S101, a semiconductor layer composed of a p type Group III-V compound semiconductor is prepared. The semiconductor layer may be composed of a Group III-V compound semiconductor crystal. Here, the semiconductor layer may be a substrate composed of a Group III-V compound semiconductor, and the semiconductor layer may be formed on the substrate.

Next, in a second step S102, gold is grown on the surface of the above semiconductor layer according to an electroless plating method to form fine gold particles. In this step, for example, when the semiconductor layer is immersed in an electroless gold plating solution, an electroless plating solution of gold is brought into contact with the surface of the semiconductor layer. In addition, in the plating treatment, the liquid temperature of the electroless gold plating solution may be room temperature (about 20° C. to 30° C.).

According to the method of producing fine gold particles in the above embodiment, fine gold particles having a particle diameter of 100 nm or more can be formed on the surface of the semiconductor layer with a density of 10⁷ cm⁻² or more.

As is well known, the electroless gold plating technology is a technology for partially laminating gold relatively thickly on an electrical wiring or the like, and is easier to handle than an electrolytic plating method. In order to produce fine gold particles by electroless gold plating, it is necessary to form a thin gold layer in an island shape on a substrate by a lithography technology so that gold plating growth is likely to occur. In addition, when electroless gold plating is performed under general conditions, since a gold deposition rate increases, it is not suitable for dispersing and arranging fine gold particles.

On the other hand, according to embodiments of the present invention, since electroless gold plating is applied to a surface of a semiconductor layer composed of a p type Group III-V compound semiconductor, larger fine gold particles having a particle diameter of 100 nm or more can be formed with a high density without forming a thin gold film in advance.

The inventors conducted extensive studies and found that large fine gold particles are formed on a semiconductor surface at appropriate intervals by electroless gold plating. In addition, they found that the diameter of fine gold particles can be controlled according to a time of immersion in an electroless gold plating solution. In an electroless gold plating method, the liquid temperature of the electroless gold plating solution is generally set to 50° C. or higher, but it was found that the deposition rate can be lowered by performing the method at room temperature of about 20° C. to 30° C. In addition, in the semiconductor layer, fine gold particles were plated and grown on the p type which was easily eluted in the solution and plating growth (deposition) was not confirmed on the n type. It is thought that, since the n type semiconductor does not easily dissolve in electroless gold plating, an oxidation-reduction reaction with gold ions is unlikely to occur, and thus plating growth is unlikely to occur.

Hereinafter, more details will be described using examples.

### Example 1

First, Example 1 will be described. “Aurexel MD” (product name, commercially available from Kanto Chemical Co., Inc.) was used as an electroless gold plating solution. 200 ml of “Aurexel MD-101A”, 40 ml of a gold nitrite(I) Na aqueous solution (commercially available from Kojima Chemicals Co., Ltd., Au 10 g/100 ml), 1 ml of “Aurexel MD-101C”, and 200 ml of “Aurexel MD-101B” were added to 500 ml of water, the mixture was stirred, and water was additionally added thereto to obtain a total amount of 1 liter, and thereby an electroless gold plating solution in Example 1 was obtained. This electroless gold plating solution did not contain cyan and an electroless gold plating of several μm at a low temperature of about 50° C. in a neutral range (pH 7.2) was possible.

In addition, for the semiconductor layer, a p type InP (111) B substrate and a p type GaAs (111) B substrate were prepared. Both were doped with Zn to obtain a p type. In addition, both substrates had a size of 1.5 cm square in a plan view.

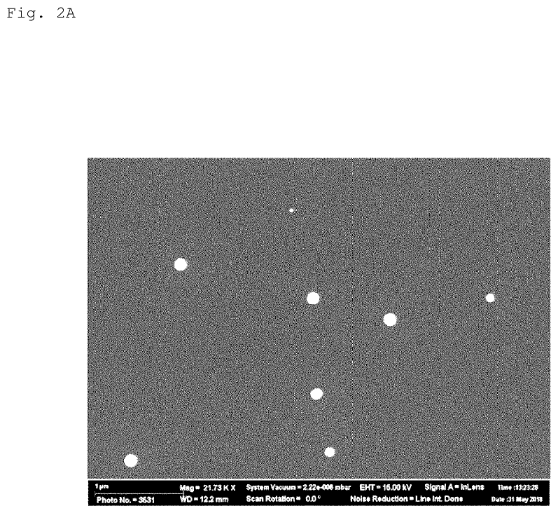

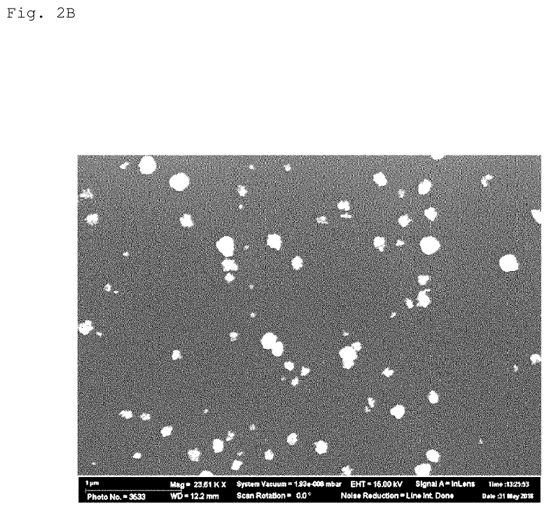

In the electroless plating treatment of Example 1, 20 ml of the above electroless gold plating solution was stored in a beaker, the p type InP (111) B substrate and the p type GaAs (111) B substrate were immersed therein, and the beaker was immersed in a bath at 30° C. for 5 minutes. The results of this electroless plating treatment are shown in FIG. 2A and FIG. 2B. FIG. 2A is a picture showing results obtained by observing a surface of a p type InP (111) B substrate under a scanning electron microscope. FIG. 2B is a picture showing results obtained by observing a surface of a p type GaAs (111) B substrate under a scanning electron microscope. As shown in FIG. 2A and FIG. 2B, it can be understood that fine gold particles having a diameter of 100 to 200 nm are formed on the surface of the substrate.

An InP nanowire was produced (grown) by a well-known vapor-liquid-solid (VLS) using the above fine gold particles. The nanowire growth was performed using a metal-organic chemical vapor deposition (MOCVD) device. In treatment conditions, the growth temperature was 420° C. In addition, an In raw material gas was formed of trimethylindium (TMIn) and supplied at 4 μmol/min. In addition, a P raw material gas was formed of tertiarybutyl phosphine (TBP) and supplied at 179 μmol/min.

In addition to the above raw material gas, in order to control (minimize) the growth in the radial direction perpendicular to a nanowire extension direction (axial direction) and form a nanowire having a uniform diameter in the axial direction, tertiarybutyl chloride (TBCl) was supplied at 7.5 μmol/min in a growth atmosphere. In addition, diethylzinc (DEZn) as a p type dopant and ditertiarybutyl sulphide (DTBS) as an n type dopant were sequentially supplied to forma diode (pn junction) structure. The growth time was 25 minutes.

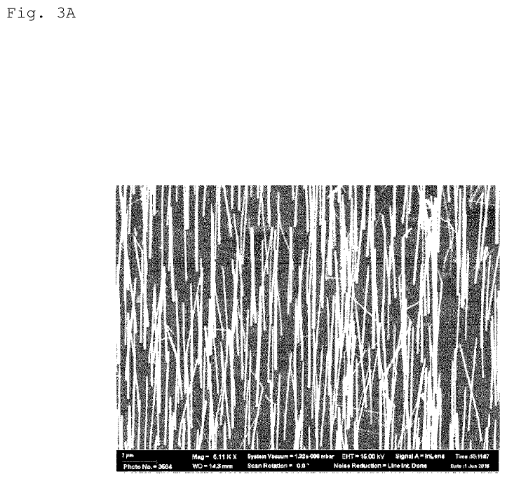

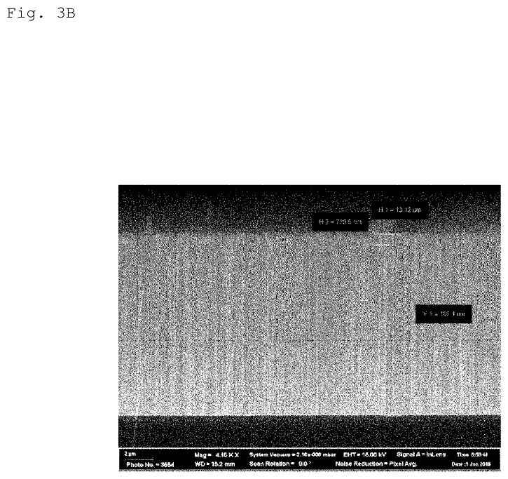

Scanning electron microscope pictures of nanowires actually produced are shown in FIG. 3A and FIG. 3B. It was confirmed that the InP nanowires were grown with a high density.

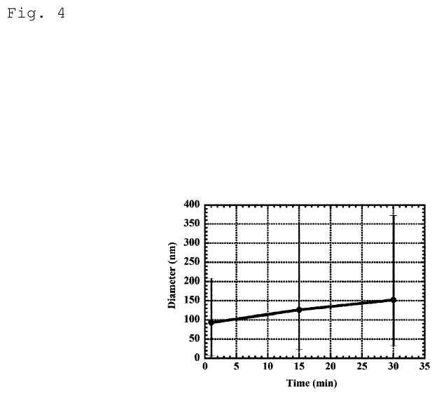

FIG. 4 shows a plating treatment time when fine gold particles were plated and grown on a surface of the p-InP (111) B substrate using the above electroless gold plating solution at a liquid temperature of 24° C., the average diameter of formed fine gold particles, and changes in the maximum value and the minimum value of the diameter. It was found that fine gold particles having a large diameter were formed as the plating treatment time increased.

### Example 2

Next, Example 2 will be described. In Example 2, fine gold particles were formed on a surface of a p-GaAs layer having a layer thickness of 100 nm grown on the InP (111) B substrate by electroless gold plating. Here, the InP (111) B substrate was doped with S to obtain an n type. In addition, the p-GaAs layer was doped with Zn.

In addition, also in Example 2, the same electroless plating solution as in Example 1 was used. In addition, the liquid temperature was set to 24° C., the treatment time was set to 5 minutes, and fine gold particles were plated and grown on the surface of the p-GaAs layer. As a result, it was confirmed that fine gold particles having a diameter of 100 to 300 nm were dispersed and formed on the surface of the p-GaAs layer with a density of about 108 cm-2.

As described above, according to embodiments of the present invention, gold was plated and grown on the surface of a p type compound semiconductor layer according to a gold electroless plating method, and thus it was possible to form larger fine gold particles with a high density more easily. According to embodiments of the present invention, it was possible to form fine gold particles in a self-aligned manner by plating growth. According to embodiments of the present invention, it was possible to realize nanowire solar cells, nanowire LEDs, and solar water decomposition and artificial photosynthetic elements with high efficiency. According to embodiments of the present invention, it was not necessary to use lithography technology or the like and it was possible to perform production at a low cost.

Here, the present invention is not limited to the embodiment described above, and obviously, many modifications and combinations can be made by those skilled in the art within the technical idea of the present invention.

1.-5. (canceled)

6. A method of producing fine gold particles, comprising:
a first step in which a semiconductor layer composed of a p-type Group III-V compound semiconductor is prepared; and
a second step in which gold is grown on a surface of the semiconductor layer according to an electroless plating method to form fine gold particles.

7. The method of producing fine gold particles according to claim 6, wherein, in the second step, an electroless plating solution of gold is brought into contact with the surface of the semiconductor layer.

8. The method of producing fine gold particles according to claim 7, wherein in the second step, a liquid temperature of the electroless plating solution of gold is in a range of 20° C. to 30° C.

9. The method of producing fine gold particles according to claim 6, wherein the semiconductor layer is composed of a Group III-V compound semiconductor crystal.

10. The method of producing fine gold particles according to claim 6, wherein the semiconductor layer is a substrate composed of a Group III-V compound semiconductor.

11. The method of producing fine gold particles according to claim 6, wherein the semiconductor layer is formed on a substrate.

12. The method of producing fine gold particles according to claim 6, wherein a density of the fine gold particles on the semiconductor layer is at least 10⁷ cm⁻², and wherein the fine gold particles have a particle diameter of 100 nm or more.

13. A method of producing gold particles, comprising:
providing a semiconductor layer composed of a p-type Group III-V compound semiconductor; and
applying an electroless plating method directly to a surface of the semiconductor layer to grow gold particles.

14. The method of producing gold particles according to claim 13, wherein the electroless plating method comprises applying an electroless plating solution of gold into contact with the surface of the semiconductor layer.

15. The method of producing gold particles according to claim 14, a liquid temperature of the electroless plating solution of gold is in a range of 20° C. to 30° C.

16. The method of producing gold particles according to claim 13, wherein the semiconductor layer is composed of a Group III-V compound semiconductor crystal.

17. The method of producing gold particles according to claim 13, wherein the semiconductor layer is a substrate composed of a Group III-V compound semiconductor.

18. The method of producing gold particles according to claim 13, wherein the semiconductor layer is formed on a substrate.

19. The method of producing gold particles according to claim 13, wherein a density of the gold particles on the semiconductor layer is at least 10⁷ cm⁻².

20. The method of producing gold particles according to claim 13, wherein the gold particles have a particle diameter of 100 nm or more.
